(19) United States
(12) Patent Application Publication
(10) Pub. No.: US 2026/0103369 A1
(43) Pub. Date: Apr. 16, 2026

(54) CONVEYANCE APPARATUS

(71) Applicant: Daifuku Co., Ltd., Nishiyodogawa-ku (JP)

(72) Inventors: Kazuya ASAHI, Shiga (JP); Takaaki IWAI, Shiga (JP)

(73) Assignee: Daifuku Co., Ltd., Nishiyodogawa-ku (JP)

(21) Appl. No.: 19/353,050

(22) Filed: Oct. 8, 2025

(30) Foreign Application Priority Data
Oct. 10, 2024 (JP) 2024-177970

(51) Int. Cl. B66F 9/18; B65G 1/04; H01L 21/677

(52) U.S. Cl. CPC B66F 9/18; B65G 1/0435; H10P 72/3206; H10P 72/3218

(57) ABSTRACT

A conveyance apparatus includes: a mast; and a lifting body supported by the mast, wherein the lifting body includes: a base; a transfer mechanism that is provided in the base, the transfer mechanism including a placement unit and an expandable unit that moves the placement unit between an inner position on the base and an outer position deviated from the base in a direction intersecting an up-down direction; and a suppression member that suppresses separation of a storage container from the placement unit by an inertial force acting upward or obliquely upward, the suppression member fixed to the base in a state of being separated upward by a predetermined distance from the base in such a manner as to be positioned above the storage container with a gap in a state where the placement unit on which the storage container is placed is at the inner position.

The present application claims priority to and incorporates by reference the entire contents of Japanese Patent Application No. 2024-177970 filed in Japan on October 10, 2024.

### BACKGROUND

### FIELD

The present disclosure relates to a conveyance apparatus.

### RELATED ART

Conventionally, there is known a conveyance apparatus which includes a mast extending in the up-down direction and a lifting body supported by the mast in such a manner as to be movable in the up-down direction and conveys a storage container of an article between two places separated from each other with the storage container placed on the lifting body (see, for example, Japanese Patent No. 6819565).

In this type of conveyance apparatuses, in cases where the conveyance speed is increased to improve the conveyance efficiency, for example, there is a possibility that a storage container floats up from the lifting body due to the inertial force and eventually separates from the lifting body when the lifting body stops from the state of moving upward or obliquely upward. In order to prevent such separation, for example, if the lifting body is structured to sandwich or grip the storage container and to move, the structure of the lifting body may become complicated or the weight of the lifting body may increase, and it may take time and effort to release the sandwiching or gripping when the storage container is taken out from or put to the lifting body.

There is a need for a conveyance apparatus capable of suppressing separation of a storage container due to the inertial force and further reducing inconvenient events associated with the suppression of the separation.

### SUMMARY

In some embodiments, a conveyance apparatus is the apparatus that conveys a storage container between two places separated in an up-down direction or a lateral direction while supporting the storage container by a lifting body, the storage container capable of storing an article. The conveyance apparatus includes: a mast that is provided in such a manner as to be movable in a lateral direction, the mast extending in the up-down direction; and a lifting body supported by the mast in such a manner as to be movable in the up-down direction and capable of stopping at a plurality of positions in the up-down direction, wherein the lifting body comprises: a base; a transfer mechanism that is provided in the base, the transfer mechanism including a placement unit on which the storage container is placed and an expandable unit that moves the placement unit between an inner position on the base and an outer position deviated from the base in a direction intersecting the up-down direction; and a suppression member that suppresses separation of the storage container from the placement unit by an inertial force acting upward or obliquely upward, the suppression member fixed to the base in a state of being separated upward by a predetermined distance from the base in such a manner as to be positioned above the storage container with a gap in a state where the placement unit on which the storage container is placed is at the inner position.

The above and other objects, features, advantages and technical and industrial significance of this disclosure will be better understood by reading the following detailed description of presently preferred embodiments of the disclosure, when considered in connection with the accompanying drawings.

### BRIEF DESCRIPTION OF THE DRAWINGS

FIG. 1 is an exemplary schematic side view of a conveyance apparatus according to an embodiment;

FIG. 2 is an exemplary schematic perspective view of a storage container conveyed by the conveyance apparatus of the embodiment;

FIG. 3 is an exemplary schematic perspective view of another storage container that is different from the one in FIG. 2 to be conveyed by the conveyance apparatus of the embodiment;

FIG. 4 is an exemplary schematic perspective view of a lifting body included in the conveyance apparatus of the embodiment;

FIG. 5 is an exemplary schematic side view illustrating a state in which the lifting body included in the conveyance apparatus of the embodiment is supporting the storage container of FIG. 2;

FIG. 6 is an exemplary schematic perspective view of suppression members included in the conveyance apparatus of the embodiment when the suppression members are viewed obliquely from below;

FIG. 7 is an exemplary schematic side view of a part of the lifting body included in the conveyance apparatus of the embodiment in the state of FIG. 5;

FIG. 8 is an exemplary schematic side view illustrating a state in which the lifting body included in the conveyance apparatus of the embodiment is supporting the storage container of FIG. 3;

FIG. 9 is a plan view of a part of the lifting body included in the conveyance apparatus of the embodiment and is an exemplary schematic plan view illustrating a state in which an expandable unit of a transfer mechanism extends in the X direction;

FIG. 10 is a plan view of a part of the lifting body included in the conveyance apparatus of the embodiment and is an exemplary schematic plan view illustrating a state in which the expandable unit of the transfer mechanism is contracted before or after the state of FIG. 9;

FIG. 11 is a plan view of a part of the lifting body included in the conveyance apparatus of the embodiment and is an exemplary schematic plan view illustrating a state in which the expandable unit of the transfer mechanism is contracted before or after the state of FIG. 12;

FIG. 12 is a plan view of a part of the lifting body included in the conveyance apparatus of the embodiment and is an exemplary schematic plan view illustrating a state in which the expandable unit of the transfer mechanism extends in the direction opposite to the X direction; and

FIG. 13 is an exemplary schematic plan view illustrating a turning locus of a support column portion of the storage container of FIG. 2 supported by the lifting body included in the conveyance apparatus of the embodiment.

### DETAILED DESCRIPTION

Hereinafter, exemplary embodiments of the present disclosure are disclosed. The structure of the embodiment described below and the actions and results (effects) obtained from the structure are one example. The present disclosure can also be implemented by a structure other than those disclosed in the following embodiment. In addition, according to the present disclosure, it is possible to obtain at least one of various effects (including derivative effects) obtained by the following structure.

In the present specification, ordinal numbers can be given for the convenience of distinguishing directions, parts, positions, portions, mechanisms, members, and the like. Note that an ordinal number does not necessarily indicate the priority or order, nor does it necessarily specify the number of items.

In each drawing, an arrow indicating a direction is illustrated. The X direction, the Y direction, and the Z direction intersect each other and are substantially orthogonal to each other. The Z direction substantially coincides with a vertically upward direction and may also be referred to as an upward direction, and a direction opposite to the Z direction may also be referred to as a downward direction. The X direction and the Y direction intersect the up-down direction and substantially coincide with a horizontal direction. The X direction and the Y direction may also be referred to as lateral directions.

### Conveyance apparatus and Storage Shelf

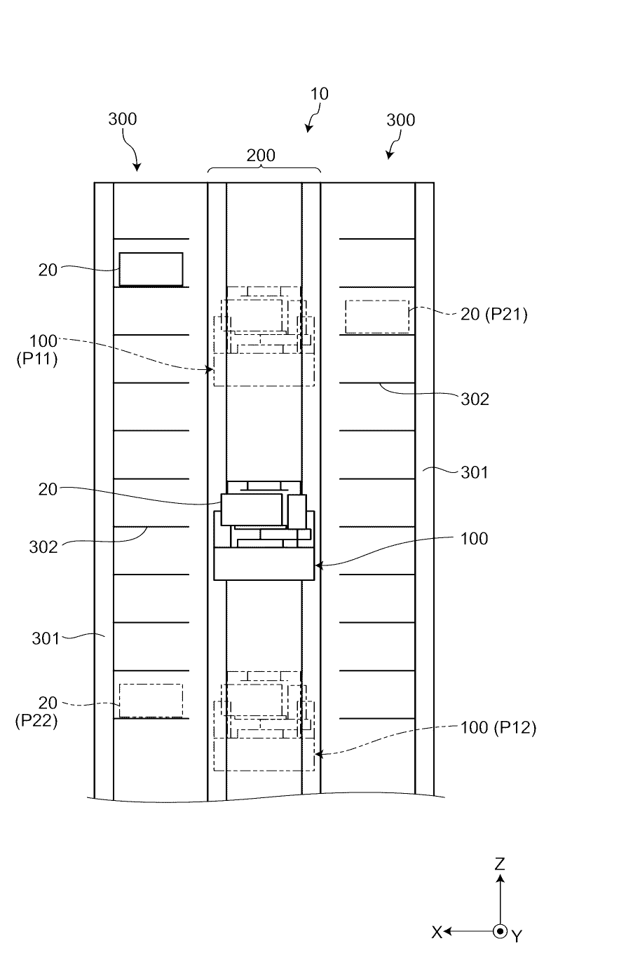

FIG. 1 is a side view of a conveyance apparatus 10 and storage shelves 300. The conveyance apparatus 10 includes a mast 200 extending in the up-down direction and a lifting body 100 supported by the mast 200 in such a manner as to be movable in the up-down direction. The lifting body 100 can stop at a plurality of positions in the Z direction. The lifting body 100 can move while supporting a storage container 20 that accommodates an article. The article accommodated in the storage container 20 is, for example, a semiconductor wafer, a circuit board, an electronic component, or the like, but is not limited thereto. The storage container 20 can also be referred to as a conveyance object.

In addition, a travelling carriage (not illustrated) capable of transporting the mast 200 in the Y direction and the direction opposite to the Y direction is provided in a lower portion of the mast 200. The travelling carriage can stop at a plurality of positions in the Y direction.

The storage shelves 300 are installed in such a manner as to be adjacent to the conveyance apparatus 10 in the X direction and the direction opposite to the X direction. The storage shelves 300 each include a support column 301 extending in the Z direction and a plurality of shelf members 302 fixed to the support column 301. The shelf members 302 are provided at predetermined intervals in the Z direction and each can support a storage container 20. The space above a shelf member 302 accommodates a storage container 20.

The storage shelves 300 are arranged on both sides of the conveyance apparatus 10 in the X direction. Each of the storage shelves 300 also extends in the Y direction and includes a plurality of shelf members 302 arranged in a matrix shape when viewed in the Y direction.

In such a structure, the lifting body 100 can be positioned at a position adjacent, in the X direction or the direction opposite to the X direction, to each of the accommodation positions (for example, P21 and P22 in FIG. 1) of the shelf members 302 arranged in the matrix shape (for example, P11 and P12 in FIG. 1). The lifting body 100 includes a transfer mechanism 120(seeFIG. 4 and others) (to be described later) capable of delivering and receiving a storage container 20 to and from a shelf member 302. The lifting body 100 can be positioned at a position (P11 or P12) facing an accommodation position (P21 or P22, respectively) and deliver a storage container 20 into the accommodation position (P21 or P22) or carry the storage container 20 out of the accommodation position (P21 or P22, respectively) using the transfer mechanism 120.

### Article

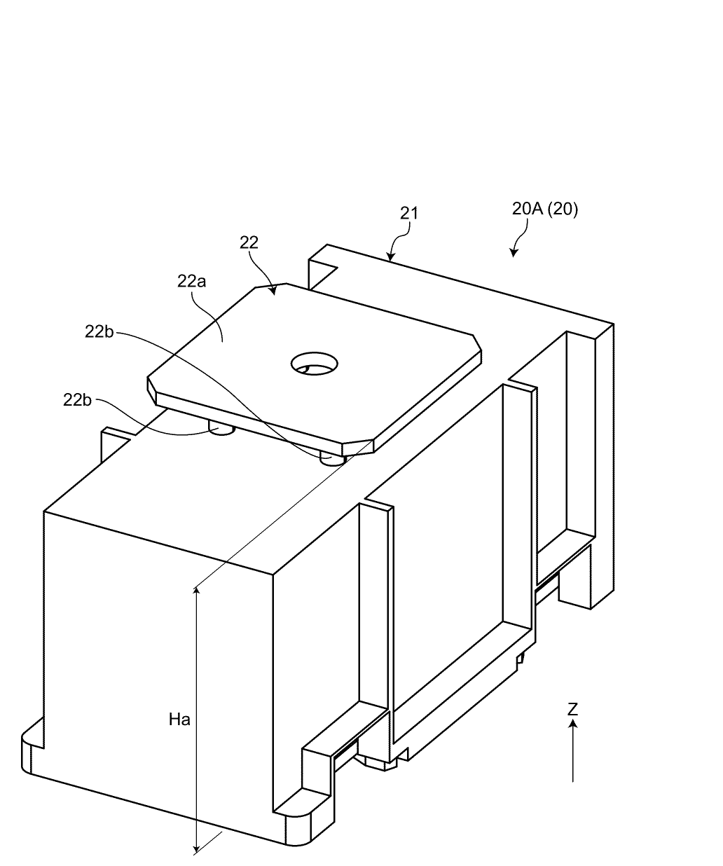

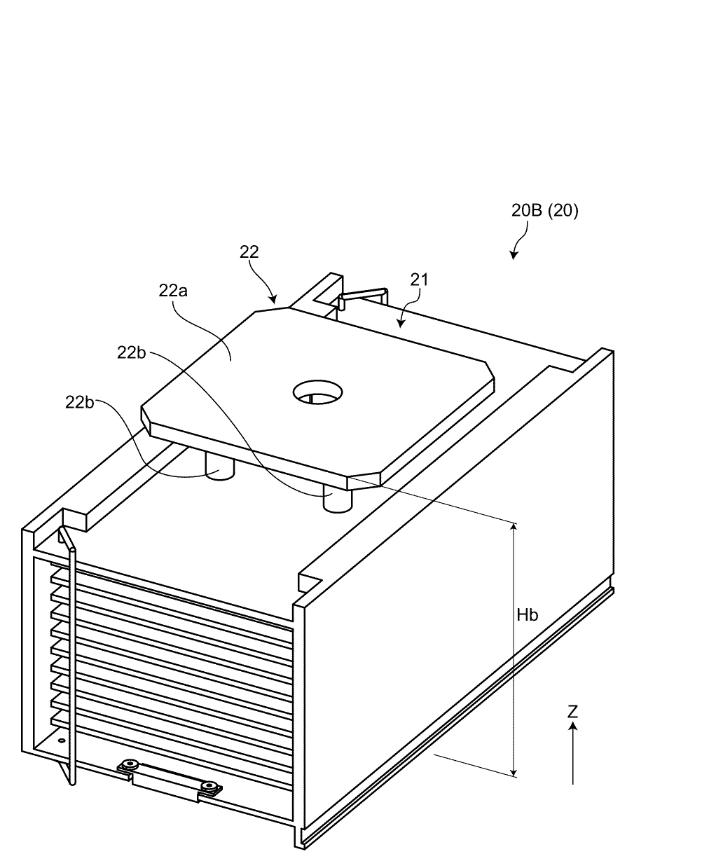

The conveyance apparatus 10 can convey a plurality of types of storage containers 20. FIGS. 2 and 3 are perspective views of the storage containers 20 (20A and 20B) as conveyance objects of the conveyance apparatus 10. As illustrated in FIGS. 2 and 3, the storage container 20A and the storage container 20B are different in structure, shape, size, dimensions (for example, heights Ha and Hb in the Z direction), and the like. In the present embodiment, the height Ha of the storage container 20A is higher than the height Hb of the storage container 20B. The storage containers 20A and 20B may also be referred to as carriers.

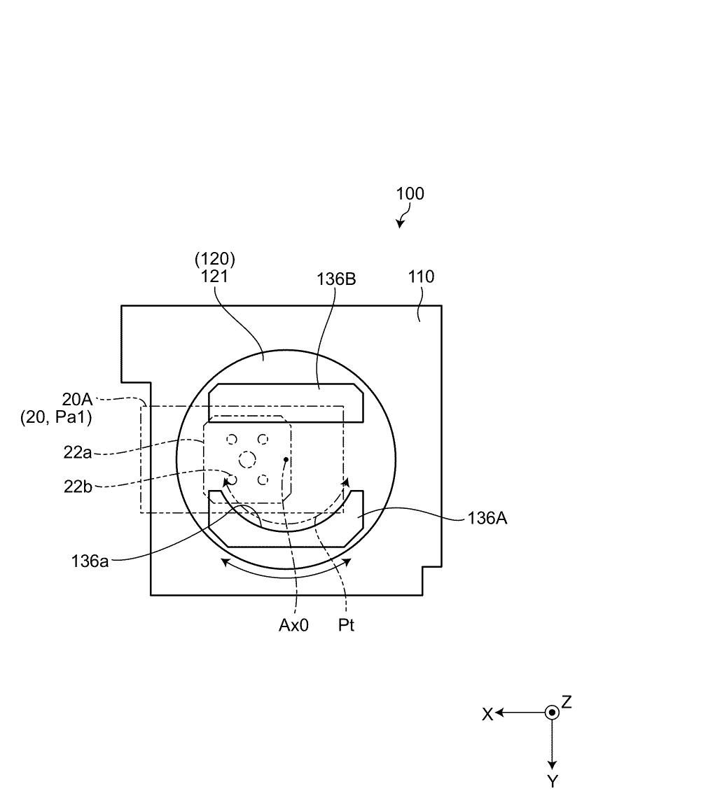

Each of the storage containers 20A and 20B includes a housing 21 and a top flange 22. The housing 21 has a substantially rectangular parallelepiped shape and accommodates a plurality of articles. In the housing 21, the articles can be accommodated in various forms. Meanwhile, the top flange 22 includes a plurality of (for example, four) support column portions 22b protruding upward from the top surface of the housing 21 and a substantially quadrangular plate-shaped portion 22a fixed to the upper ends of the support column portions 22b and extending orthogonally to the Z direction. In the examples of FIGS. 2 and 3, the support column portions 22b are arranged at positions of vertices of corners of a virtual square intersecting the Z direction (see FIG. 13). In FIGS. 2 and 3, only two support column portions 22b are illustrated. Note that the top flange 22 is used for gripping or holding the storage container 20 in a conveyance apparatus, a processing apparatus, or the like other than the conveyance apparatus 10 of the present embodiment.

### Lifting Body

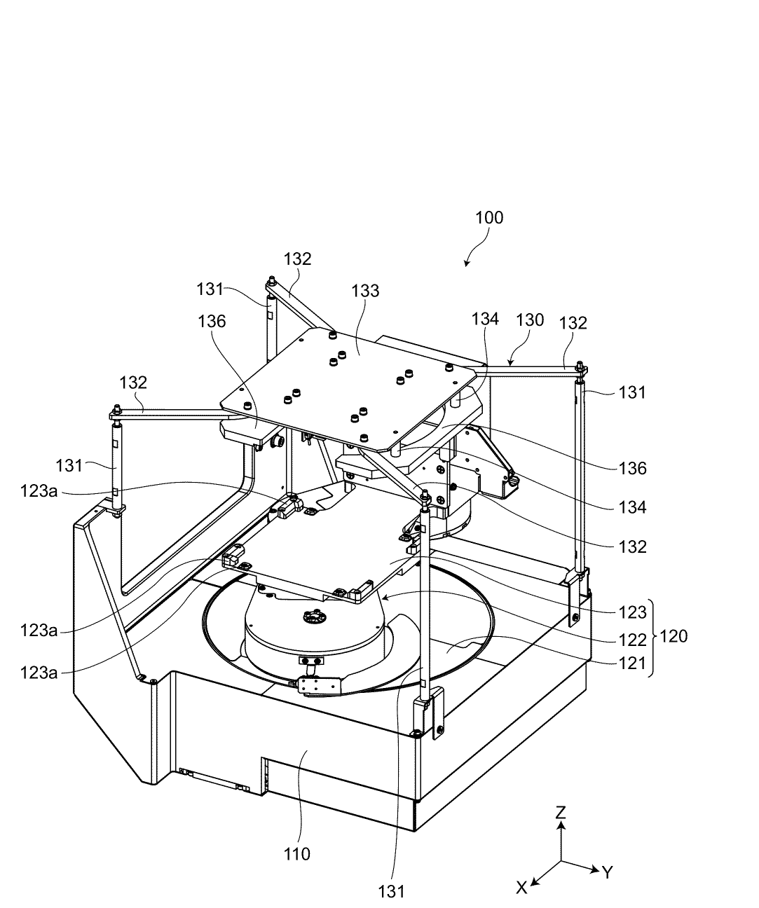

FIG. 4 is a perspective view of the lifting body 100. As illustrated in FIG. 4, the lifting body 100 includes a base 110, a transfer mechanism 120, and a suppression structure 130.

The base 110 has a flat and substantially rectangular parallelepiped shape and is movably fixed to the mast 200 (see FIG. 1).

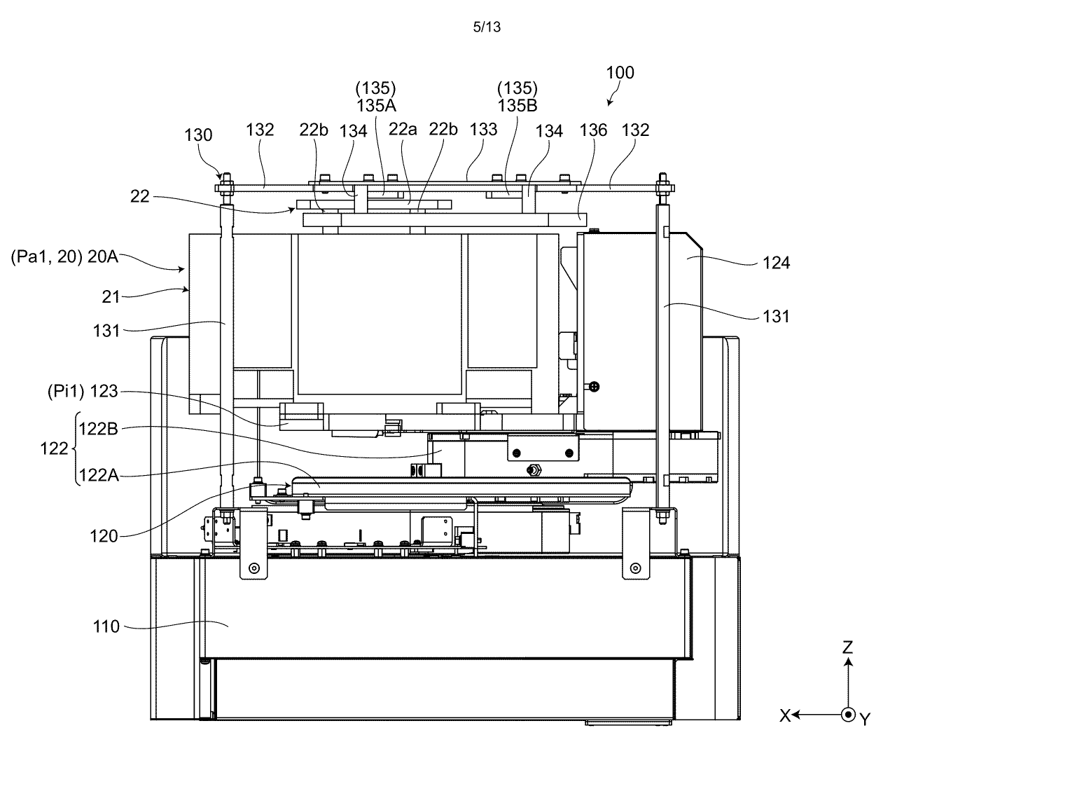

The transfer mechanism 120 includes a turning unit 121, an expandable arm 122, a placement unit 123, and a housing 124 (see FIG. 5).

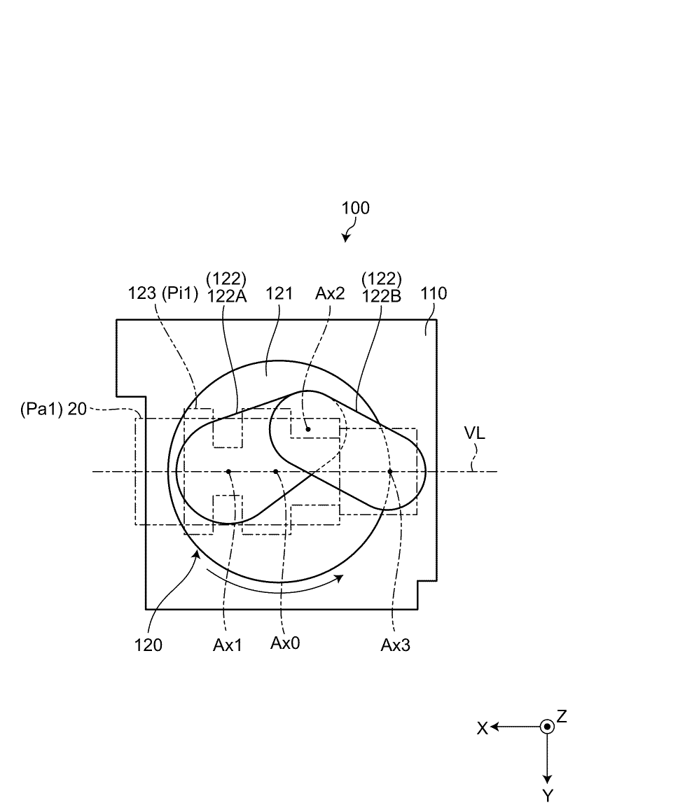

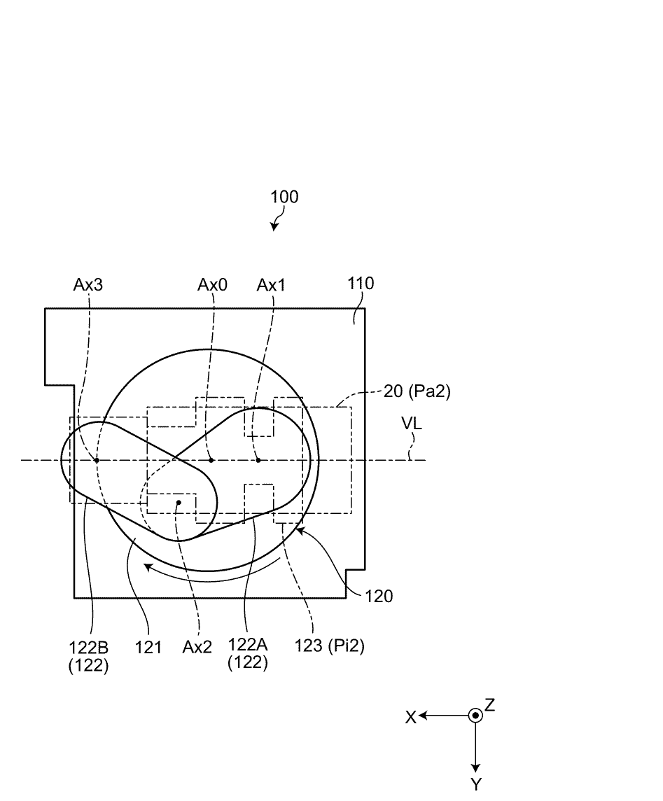

The turning unit 121 has a substantially disk shape and is accommodated in a substantially circular opening formed in the base 110. The turning unit 121 can turn relative to the base 110 about a turning axis Ax0 (see FIGS. 10 and 11 and others) extending in the Z direction.

The expandable arm 122 is interposed between the turning unit 121 and the placement unit 123 and is structured as a serial link arm including a plurality of arms turnably connected to each other. The expandable arm 122 is an example of the expandable unit.

The placement unit 123 is a substantially plate-like member connected to the distal end of the expandable arm 122 and extending orthogonally to the Z direction and is a portion on which a storage container 20 is placed. The placement unit 123 has a plurality of protrusions 123a made of an elastic material such as an elastomer. The storage container 20 is positioned with respect to the placement unit 123 by being partially clamped in directions intersecting the Z direction (X direction and Y direction) by the plurality of protrusions 123a.

The housing 124 accommodates, for example, a control device including a circuit board, electric components, and the like, a drive mechanism including a motor, gears, and the like or others.

### Suppression Structure

FIG. 5 is a side view of the lifting body 100 in a state of supporting the storage container 20A of FIG. 2. As illustrated in FIGS. 4 and 5, the suppression structure 130 is fixed to the base 110. Furthermore, as illustrated in FIG. 5, a part of the suppression structure 130 partially covers the storage container 20 placed on the placement unit 123 from above with a gap therebetween. As described above, the lifting body 100 moves between a plurality of positions (for example, P11 and P12). In this example, in a case where the lifting body 100 on which the storage container 20 is placed moves in a direction having an upward direction (Z direction) component, for example, in the upward direction or an obliquely upward direction (for example, a direction inclined toward the Y direction or a direction opposite to the Y direction with respect to the Z direction), the inertial force acts on the storage container 20 in the upward direction or the obliquely upward direction when the lifting body 100 stops at a destination position. The inertial force tends to be greater as the moving speed grows faster, and eventually, it becomes easier for the storage container 20 to float upward or obliquely upward from the placement unit 123. In a structure in which no countermeasure is taken, there is a possibility that the storage container 20 is separated from the placement unit 123. In this respect, according to the present embodiment, since the suppression structure 130 covers the storage container 20 from above with the gap, even if the storage container 20 floats upward or obliquely upward from the placement unit 123, the storage container 20 interferes with the suppression structure 130 (with interference portions 135 and 136 thereof), and thus the storage container 20 cannot move further upward from the position of interference with the suppression structure 130. As a result, the suppression structure 130 can suppress separation of the storage container 20 from the placement unit 123.

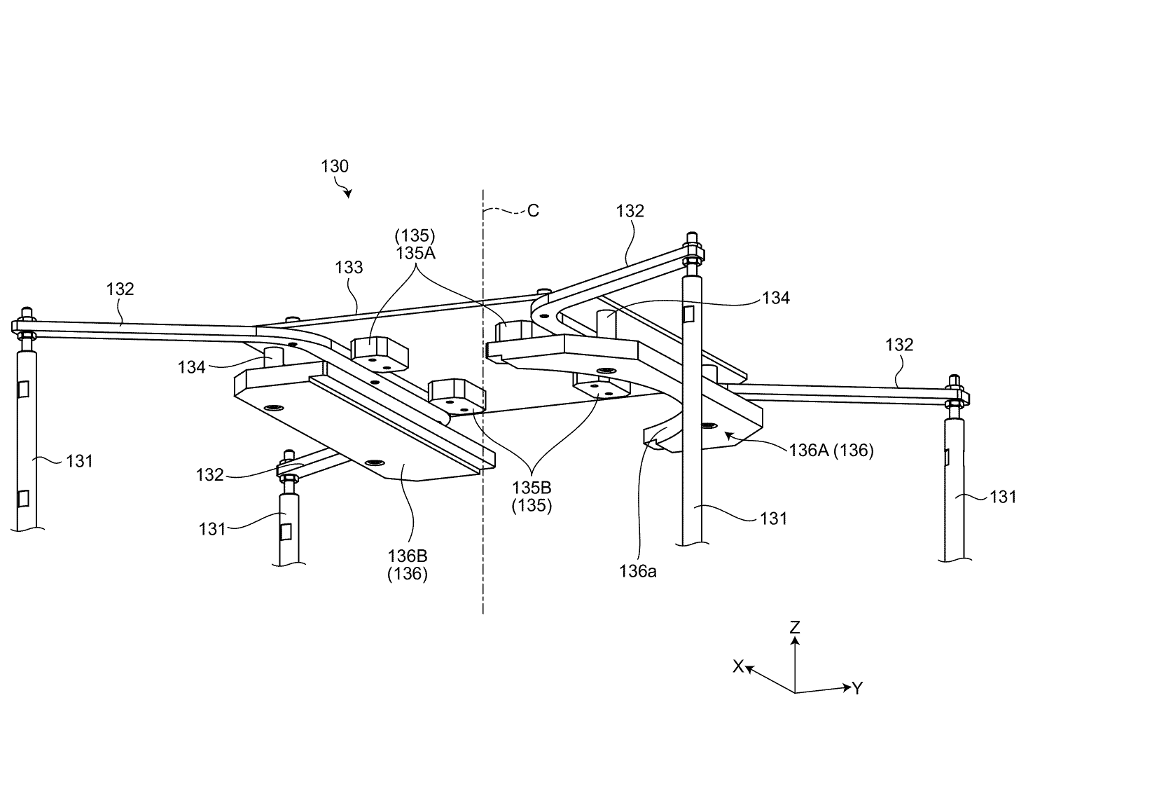

FIG. 6 is a perspective view of an upper portion of the suppression structure 130 as viewed obliquely from below. As illustrated in FIGS. 4 and 6, the suppression structure 130 includes columns 131, beams 132, a top plate portion 133, connecting portions 134, and interference portions 135 and 136.

The suppression structure 130 includes four columns 131. Each of the columns 131 extends in the Z direction (upward) from the vicinity of one of four corners of the base 110 when viewed in the direction opposite to the Z direction. In order not to interfere with the storage container 20 placed on the placement unit 123, a column 131 is provided at a position shifted laterally (in a direction intersecting the Z direction) with respect to the storage container 20 placed on the placement unit 123. The columns 131 are an example of the extending portions.

The suppression structure 130 includes four beams 132. Each of the beams 132 extends from the upper end of one of the columns 131 in such a manner as to approach a position overlapping with a substantially central portion of the base 110 when viewed in the direction opposite to the Z direction. As illustrated in FIG. 6, in the present embodiment, as an example, two beams 132 are connected via a middle portion to form one substantially U-shaped member; however, it is not limited to such a structure. That is, the four beams 132 may be independent members.

The top plate portion 133 is joined to portions of the four beams 132 away from the columns 131. The top plate portion 133 is provided in such a manner as to substantially overlap with a substantially central portion of the base 110 when viewed in the direction opposite to the Z direction.

The suppression structure 130 includes four connecting portions 134. Each of the connecting portions 134 extends downward from a position close to the peripheral edge of the top plate portion 133.

The suppression structure 130 further includes the interference portions 135 and 136. In the present embodiment, the suppression structure 130 includes four interference portions 135 and two interference portions 136.

Each of the interference portions 135 protrudes downward from the surface of the top plate portion 133 facing the direction opposite to the Z direction (back surface or lower surface). The positions of the ends (lower ends) of the four interference portions 135 in the Z direction are substantially the same.

The four interference portions 135 include two interference portions 135A and two interference portions 135B. The two interference portions 135A are arranged at an interval in the Y direction. In addition, the two interference portions 135B are separated from the two interference portions 135A in the direction opposite to the X direction and are arranged at an interval in the Y direction. When viewed in the direction opposite to the Z direction, the four interference portions 135 are arranged around a center line C passing through the center (center of gravity) of the top plate portion 133 and extending in the Z direction. The two interference portions 135A are separated from the center line C in the X direction, and the two interference portions 135B are separated from the center line C in the direction opposite to the X direction. In addition, the two interference portions 135A include an interference portion 135 separated from the center line C in the Y direction and an interference portion 135 separated from the center line C in the direction opposite to the Y direction, and the two interference portions 135B also include an interference portion 135 separated from the center line C in the Y direction and an interference portion 135 separated from the center line C in the direction opposite to the Y direction.

Each of the interference portions 136 is fixed to the ends (lower ends) of connecting portions 134 in the direction opposite to the Z direction. At least a part of the interference portion 136 is shifted in the direction opposite to the Z direction with respect to the interference portion 135. That is, the separation distance of an interference portion 136 from the base 110 in the Z direction is shorter than the upward separation distance of an interference portion 135 from the base 110.

The two interference portions 136 include an interference portion 136A and an interference portion 136B. The interference portions 136A and 136B are arranged at an interval in the Y direction. The positions in the Z direction of the ends of the interference portions 136A and 136B in the direction opposite to the Z direction are substantially the same. The interference portion 136A is separated from the center line C in the Y direction, and the interference portion 136B is separated from the center line C in the direction opposite to the Y direction. In addition, each of the two interference portions 135A and 136B extends substantially in the X direction between one end separated from the center line C in the X direction and the other end separated from the center line C in the direction opposite to the X direction.

As described above, FIG. 5 illustrates a state in which the storage container 20A of FIG. 2 is placed on the placement unit 123. In the state of FIG. 5, the lifting body 100 is structured in such a manner that at least a part of both of the two interference portions 135A separated from each other in the Y direction (see FIG. 6) is positioned above a part of the plate-shaped portion 22a of the storage container 20A with a slight gap. With this structure, when the lifting body 100 moves upward or obliquely upward and stops in the state of FIG. 5, even in a case where the inertial force acts on the storage container 20A upward or obliquely upward, the storage container 20A can be separated from the placement unit 123 only by a minute distance in which the plate-shaped portion 22a abuts on the interference portion 135A. Therefore, the interference portion 135A of the suppression structure 130 can suppress separation of the storage container 20A from the placement unit 123, namely, the lifting body 100. The interference portions 135 are an example of suppression members and an example of a first suppression member.

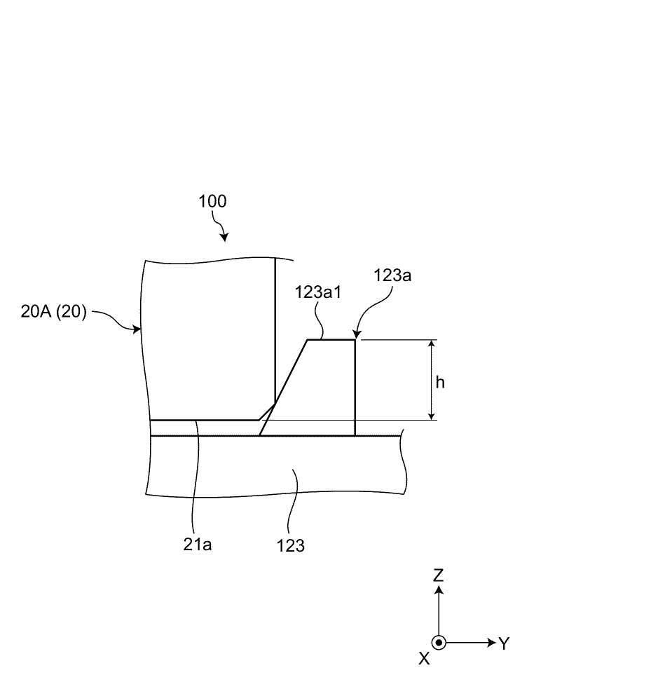

FIG. 7 is a side view of a part of the lifting body 100 including the placement unit 123 and the storage container 20A in the state of FIG. 5. As illustrated in FIG. 7, let the distance in the Z direction (up-down direction) between a bottom 21a, as the lower end of the storage container 20A supported by the placement unit 123, and an upper end 123a1 of a protrusion 123a be h. In this case, the lifting body 100 of the present embodiment is structured in such a manner that the gap in the Z direction between the plate-shaped portion 22a and the interference portion 135A in the state of FIG. 5, namely, the minimum gap in the Z direction between the storage container 20A and the suppression structure 130 is smaller than the distance h. According to this structure, in a case where the inertial force acts upward or obliquely upward on the storage container 20A, even when the storage container 20A is separated from the placement unit 123, the storage container 20A interferes with the interference portions 135 before climbing over the protrusion 123a and thus cannot climb over the protrusion 123a. Therefore, according to this structure, it is possible to more reliably prevent the storage container 20A from being separated from the placement unit 123, namely, the lifting body 100.

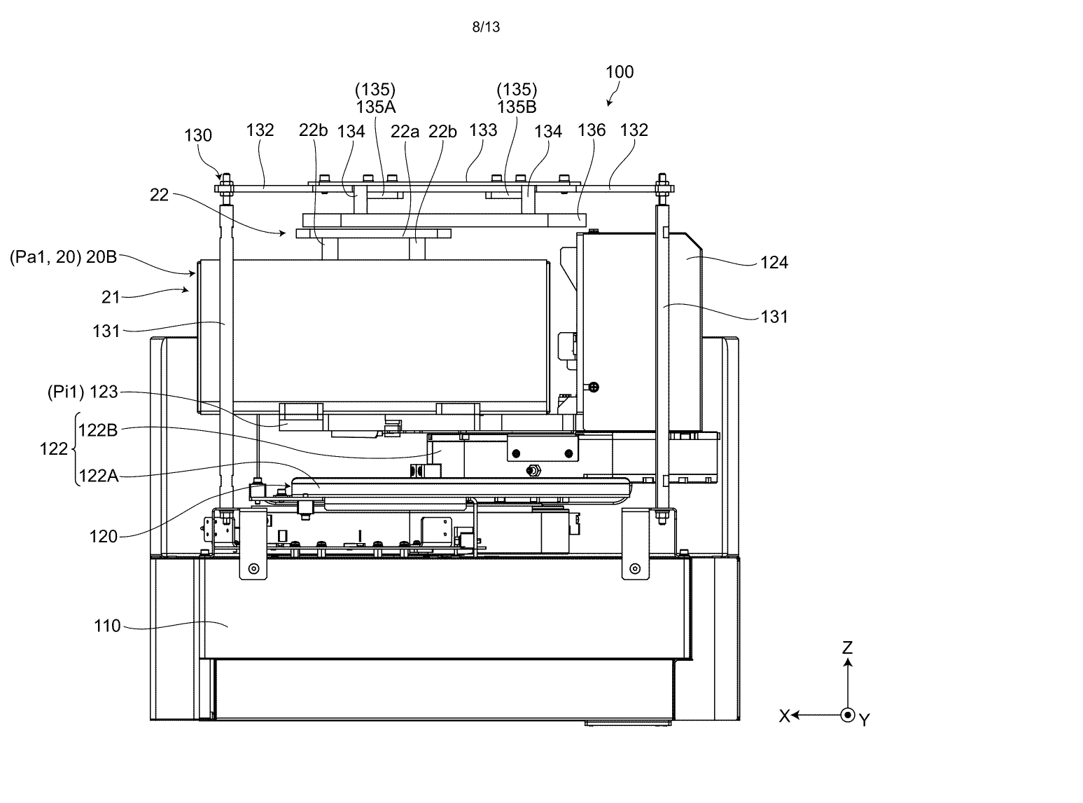

FIG. 8 is a side view of the lifting body 100 in the state of supporting the storage container 20B of FIG. 3. In the state of FIG. 8, the lifting body 100 is structured in such a manner that a part of both of the two interference portions 136A and 136B (see FIG. 6) separated in the Y direction is positioned above a part of the plate-shaped portion 22a of the storage container 20B with a slight gap. With this structure, when the lifting body 100 moves upward or obliquely upward and stops in the state of FIG. 8, even in a case where the inertial force acts on the storage container 20B upward or obliquely upward, the storage container 20B can be separated from the placement unit 123 only by a minute distance in which the plate-shaped portion 22a abuts on the interference portions 136A and 136B. Therefore, the interference portions 136A and 136B of the suppression structure 130 can suppress separation of the storage container 20B from the placement unit 123, namely, the lifting body 100. The interference portions 136 are an example of the suppression members and an example of a second suppression member. In the state of FIG. 8, portions of the interference portions 136A and 136B positioned on the X direction side with respect to the central portion in the X direction face the plate-shaped portion 22a.

In addition, the lifting body 100 is structured in such a manner that the gap in the Z direction between the plate-shaped portion 22a and the interference portions 136A and 136B in the state of FIG. 8, namely, the minimum gap in the Z direction between the storage container 20B and the suppression structure 130 is smaller than the distance h illustrated in FIG. 7. According to this structure, in a case where the inertial force acts upward or obliquely upward on the storage container 20B, even when the storage container 20B is separated from the placement unit 123, the storage container 20B interferes with the interference portions 136 before climbing over the protrusion 123a and thus cannot climb over the protrusion 123a. Therefore, according to this structure, it is possible to more reliably prevent the storage container 20B from being separated from the placement unit 123, namely, the lifting body 100.

### Transfer Mechanism

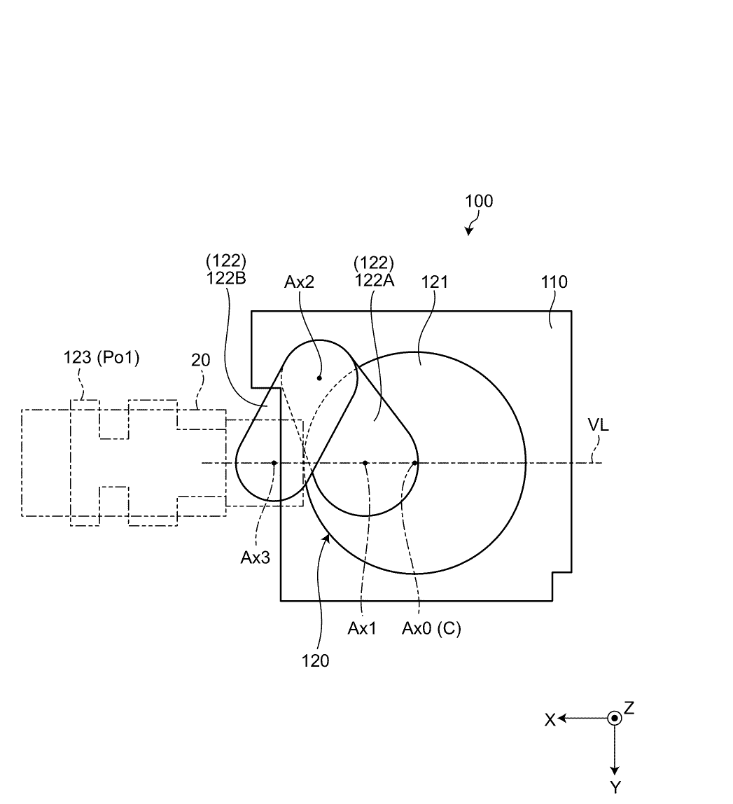

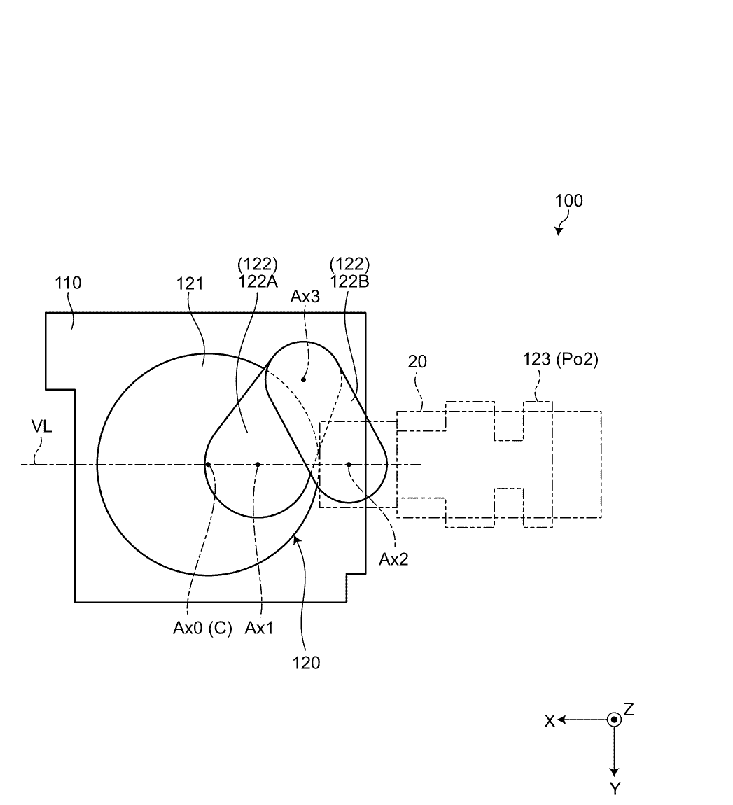

FIGS. 9 to 12 are plan views illustrating the operation of the transfer mechanism 120. FIG. 9 illustrates a state in which the expandable arm 122 extends in the X direction, FIG. 10 illustrates a state in which the expandable arm 122 contracts before extending in the X direction or after extending in the X direction, FIG. 11 illustrates a state in which the expandable arm 122 contracts before extending in the direction opposite to the X direction or after extending in the X direction, and FIG. 12 illustrates a state in which the expandable arm 122 extends in the direction opposite to the X direction. The X direction is a carrying-in direction of a storage container 20 into the lifting body 100 and is also a carrying-out direction from the lifting body 100.

As illustrated in FIG. 9 to 12, the expandable arm 122 includes a plurality of arm portions 122A and 122B. The proximal end of the arm portion 122A is connected to the turning unit 121 in such a manner as to be relatively turnable about a turning axis Ax1 extending in the Z direction, and the proximal end of the arm portion 122B is connected to the distal end of the arm portion 122A in such a manner as to be relatively turnable about a turning axis Ax2 extending in the Z direction. Furthermore, the placement unit 123 is connected to the distal end of the arm portion 122B in such a manner as to be relatively turnable about a turning axis Ax3 extending in the Z direction. The relative turning of each portion about the turning axes Ax0 to Ax3 is implemented by a motor (not illustrated), a turning mechanism such as a gear, a belt, or a pulley, and a power transmission mechanism. In the present embodiment, the turning axis Ax0 substantially coincides with the center line C of the suppression structure 130 described above but does not necessarily coincide with the center line C.

The expandable arm 122 extends and contracts between the protruding state in the X direction in FIG. 9 and the retracting state in FIG. 10, whereby the placement unit 123 can be moved between an outer position Po1 in FIG. 9 and an inner position Pi1 in FIG. 10. The outer position Po1 is a position deviated from the base 110 in the X direction intersecting the Z direction and is a position where a storage container 20 is transferred between the placement unit 123 and the outside of the placement unit 123 (for example, the accommodation positions on the shelf members 302 (P21 and P22)). In addition, as illustrated in FIGS. 5 and 8, the inner position Pi1 is a position on the base 110 and is a position for holding the storage container 20 when the lifting body 100 moves. Between the outer position Po1 and the inner position Pi1, the operation of the motor is controlled in such a manner that the placement unit 123 moves translationally in the X direction and in the direction opposite to the X direction in plan view. In this case, the turning axes Ax1 and Ax3 move on a virtual line VL passing through the turning axis Ax0 and extending in the X direction. The X direction and the direction opposite to the X direction can be referred to as a moving direction of the placement unit 123. Note that, in the protruding state in the X direction exemplified in FIG. 9, the expandable arm 122 is bent; however, it is not limited thereto. In the protruding state, the expandable arm 122 may be in an extended state of extending straight without being bent or may be in a bent state of being bent at an angle different from that in FIG. 9.

On the other hand, the expandable arm 122 extends and contracts between the protruding state in the direction opposite to the X direction in FIG. 12 and the retracting state in FIG. 11, whereby the placement unit 123 can be moved between an outer position Po2 in FIG. 12 and an inner position Pi2 in FIG. 11. The outer position Po2 is a position deviated from the base 110 in the direction opposite to the X direction and is a position where the storage container 20 is transferred between the placement unit 123 and the outside of the placement unit 123. In addition, the inner position Pi2 is a position on the base 110 and is a position for holding the storage container 20 when the lifting body 100 moves. Also between the outer position Po2 and the inner position Pi2, the operation of the motor is controlled in such a manner that the placement unit 123 moves translationally in the X direction and in the direction opposite to the X direction in plan view. Also in this case, the turning axes Ax1 and Ax3 move on the virtual line VL. Note that, in the protruding state in the direction opposite to the X direction exemplified in FIG. 12, the expandable arm 122 is bent; however, it is not limited thereto. In the protruding state, the expandable arm 122 may be in an extended state of extending straight without being bent or may be in a bent state of being bent at an angle different from that in FIG. 12.

In addition, the transfer mechanism 120 turns about the turning axis Ax0 between the state of FIG. 10 and the state of FIG. 11. In this example, the inner position Pi1 in FIG. 10 and the inner position Pi2 in FIG. 11 are shifted in the X direction. This is because, as illustrated in FIGS. 5 and 8, the placement unit 123 and the housing 124 are arranged in the X direction, and a substantially central portion in the X direction of a subassembly including the placement unit 123 and the housing 124 is positioned on the turning axis Ax0. Accordingly, a position Pa1 (see FIG. 10) of the storage container 20 in a case where the placement unit 123 is at the inner position Pi1 and a position Pa2 (see FIG. 11) of the storage container 20 in a case where the placement unit 123 is at the inner position Pi2 are also shifted in the X direction.

Meanwhile, the interference portions 135 include the interference portion 135A and the interference portion 135B separated from each other in the X direction. That is, as illustrated in FIG. 5, when the placement unit 123 is positioned at the inner position Pi1 and the storage container 20A is positioned at the position Pa1, the interference portion 135A faces the plate-shaped portion 22a of the storage container 20A with a gap and can function as suppression members. On the other hand, when the placement unit 123 is positioned at the inner position Pi2 and the storage container 20A is positioned at the position Pa2, the interference portion 135B faces the plate-shaped portion 22a of the storage container 20A with a gap and can function as suppression members.

An interference portion 136 has a shape extending in the X direction. As a result, as illustrated in FIG. 8, when the placement unit 123 is positioned at the inner position Pi1 and the storage container 20B is positioned at the position Pa1, portions of the interference portions 136A and 136B on the end side with respect to the central portion in the X direction face the plate-shaped portion 22a of the storage container 20A with a gap and can function as suppression members. Meanwhile, when the placement unit 123 is positioned at the inner position Pi2 and the storage container 20B is positioned at the position Pa2, portions of the interference portions 136A and 136B on the end side in the direction opposite to the X direction with respect to the central portion face the plate-shaped portion 22a of the storage container 20B with a gap and can function as suppression members.

FIG. 13 is a plan view illustrating a turning locus Pt of a support column portion 22b of the storage container 20A supported by the placement unit 123 when the transfer mechanism 120 including the turning unit 121 turns about the turning axis Ax0 between the state of FIG. 10 and the state of FIG. 11. As illustrated in FIGS. 5, 10, and 13, in a state where the placement unit 123 is positioned at the inner position Pi1 and the storage container 20A is positioned at the position Pa2, the interference portions 136 do not interfere with the storage container 20A. However, as illustrated in FIG. 13, when the transfer mechanism 120 including the turning unit 121 turns about the turning axis Ax0 between the state of FIG. 10 and the state of FIG. 11, the support column portion 22b of the storage container 20A supported by the transfer mechanism 120 moves in the Y direction when the transfer mechanism 120 turns. Therefore, if the interference portion 136A has a rectangular plate shape extending in the X direction, the interference portion 136A and the support column portion 22b may interfere with each other. Therefore, in the present embodiment, the interference portion 136A includes an arc-shaped recess 136a that is recessed on the side opposite to the turning axis Ax0, namely, in the Y direction. As a result, it is possible to avoid interference between the turning support column portion 22b, namely, the storage container 20A, and the interference portion 136A. Note that the recess 136a only needs to be at a position farther from the turning axis Ax0 with respect to the turning locus Pt of a portion of the support column portion 22b that is the farthest from the turning axis Ax0 in a plan view seen in the direction opposite to the Z direction and does not need to have an arc shape. In a case where the support column portion 22b turns in a locus moving in the direction opposite to the Y direction, in order to avoid interference with the support column portion 22b, the interference portion 136B may include a recess recessed on the opposite side of the turning axis Ax0, namely, in the direction opposite to the Y direction.

As described above, in the present embodiment, the interference portions 135 and 136 (suppression members) are fixed to the base 110 in a state of being separated upward by a predetermined distance from the base 110 in such a manner as to be positioned above a storage container 20 with a gap in a state where the placement unit 123 is at the inner positions Pi1 and Pi2. According to this structure, when the storage container 20 floats up from the placement unit 123 by the inertial force acting upward or obliquely upward, the interference portions 135 and 136 interfere with the storage container 20, whereby the storage container 20 can be suppressed from being separated from the placement unit 123. In addition, according to this structure, as compared with a structure in which the storage container 20 is clamped or gripped, it is possible to further simplify the structure for suppressing the separation of the storage container 20, and accordingly, there are advantages that it is possible to reduce the labor and cost of manufacturing and to more smoothly and quickly transfer the storage container 20.

In addition, in the present embodiment, the lifting body 100 includes the plurality of columns 131 (extending portions) extending upward from the base 110 at positions on sides of the storage container 20 in a state where the storage container 20 is placed on the placement unit 123, and the interference portions 135 and 136 are fixed to the base 110 via the columns 131. According to this structure, the interference portions 135 and 136 can be arranged above the storage container 20 with a relatively simple structure while avoiding interference with the storage container 20. Furthermore, by fixing the interference portions 135 and 136 to the base 110 via the plurality of columns 131, for example, as compared with a structure in which the interference portions 135 and 136 are supported in a cantilever manner by the base 110 or the placement unit 123 via one column (extending portion), the interference portions 135 and 136 can be implemented as a more rigid, more robust, and more stable structure.

In addition, in the present embodiment, the suppression structure 130 includes the interference portions 135 (first suppression member) that interfere with the storage container 20A and the interference portions 136 (second suppression member) whose separation distance from the base 110 in the Z direction is shorter than that of the interference portions 135. According to this structure, it is possible to suppress separation of both the storage containers 20A and 20B having different heights from the placement unit 123 using the interference portions 135 and 136.

Furthermore, in the present embodiment, the transfer mechanism 120 is provided in the base 110 in such a manner as to be turnable about the turning axis Ax0, and the interference portion 136 includes the recess 136a that avoids interference with the storage container 20A when the storage container 20A to be prevented from being separated by the interference portion 135 turns as the transfer mechanism 120 turns. According to this structure, it is possible to prevent the interference portions 136 from hindering the turning of a storage container 20.

Although the embodiment of the present disclosure has been exemplified above, the above embodiment is merely an example and is not intended to limit the scope of the disclosure. The above-described embodiment can be implemented in various other forms, and various omissions, substitutions, combinations, and modifications can be made without departing from the gist of the disclosure. In addition, specifications such as each structure or shape (structure, type, direction, model, size, length, width, thickness, height, number of items, arrangement, position, material, etc.) can be modified as appropriate for implementation.

For example, the expandable unit may include a plurality of members that relatively slide linearly in the expansion and contraction direction and may have a structure different from that of the above embodiment in which the entire length changes. Furthermore, the storage container may have various structures.

The structure in which the base supports the first suppression member and the second suppression member can be variously modified and implemented. For example, the base may be connected to the second suppression member via an extending portion or the like, and the first suppression member and the second suppression member may be connected via a connection member extending from the second suppression member. In addition, a suppression member, a member included in the extending portion between the base and the suppression member, and the like may be structured to be replaceable or may be structured to changeable (adjustable) in terms of the length, the connection position, or the like.

Furthermore, the first suppression member may extend long in the moving direction of the placement unit, or the second suppression member may be divided in the moving direction of the placement unit.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A conveyance apparatus that conveys a storage container between two places separated in an up-down direction or a lateral direction while supporting the storage container by a lifting body, the storage container capable of storing an article, the conveyance apparatus comprising:
a mast that is provided in such a manner as to be movable in a lateral direction, the mast extending in the up-down direction; and
a lifting body supported by the mast in such a manner as to be movable in the up-down direction and capable of stopping at a plurality of positions in the up-down direction,
wherein the lifting body comprises:
a base;
a transfer mechanism that is provided in the base, the transfer mechanism including
a placement unit on which the storage container is placed and
an expandable unit that moves the placement unit between an inner position on the base and an outer position deviated from the base in a direction intersecting the up-down direction; and
a suppression member that suppresses separation of the storage container from the placement unit by an inertial force acting upward or obliquely upward, the suppression member fixed to the base in a state of being separated upward by a predetermined distance from the base in such a manner as to be positioned above the storage container with a gap in a state where the placement unit on which the storage container is placed is at the inner position.

2. The conveyance apparatus according to claim 1,
wherein the lifting body includes a plurality of extending portions extending upward from the base at positions on sides of the storage container in a state where the storage container is placed on the placement unit, and
the suppression member is fixed to the base via the plurality of extending portions.

3. The conveyance apparatus according to claim 1, wherein the suppression member includes
a first suppression member and
a second suppression member having an upward separation distance from the base shorter than that of the first suppression member.

4. The conveyance apparatus according to claim 2, wherein the suppression member includes
a first suppression member and
a second suppression member having an upward separation distance from the base shorter than that of the first suppression member.

5. The conveyance apparatus according to claim 3,
wherein the transfer mechanism is provided in the base in such a manner as to be turnable about a turning axis extending in the up-down direction,
each of the first suppression member and the second suppression member is structured to suppress separation of one of a plurality of the storage containers having different heights from the base in a state of being placed on the base, and
the second suppression member includes a recess that avoids interference with the storage container when the storage container to be suppressed from being separated by the first suppression member turns as the transfer mechanism turns.

6. The conveyance apparatus according to claim 4,
wherein the transfer mechanism is provided in the base in such a manner as to be turnable about a turning axis extending in the up-down direction,
each of the first suppression member and the second suppression member is structured to suppress separation of one of a plurality of the storage containers having different heights from the base in a state of being placed on the base, and
the second suppression member includes a recess that avoids interference with the storage container when the storage container to be suppressed from being separated by the first suppression member turns as the transfer mechanism turns.
